(19) United States
(12) Patent Application Publication
(10) Pub. No.: US 2015/0364532 A1
(43) Pub. Date: Dec. 17, 2015

(54) INDUCTOR FORMED ON A SEMICONDUCTOR SUBSTRATE

(71) Applicant: UNITED MICROELECTRONICS CORP., Hsin-Chu City (TW)

(72) Inventors: Yung-Chang Lin, Taichung City (TW); Chien-Li Kuo, Hsinchu City (TW)

(21) Appl. No.: 14/341,848

(22) Filed: Jul. 28, 2014

(30) Foreign Application Priority Data
Jun. 13, 2014 (TW) 103120613

(51) Int. Cl. H01L 49/02; H01L 23/522

(52) U.S. Cl. CPC H01L 28/10; H01L 23/5226

(57) ABSTRACT

An inductor formed on a semiconductor substrate includes a semiconductor substrate, an inductor structure formed on the semiconductor substrate, and a plurality of slice structures formed in the semiconductor substrate. An extending direction of the slice structures is perpendicular to a surface of the semiconductor substrate. The slice structures are overlapped by the inductor.

### BACKGROUND OF THE INVENTION

1. Field of the Invention

The present invention relates to an inductor formed on a semiconductor substrate, and more particularly, to an inductor formed on a semiconductor substrate capable of avoiding eddy currents.

2. Description of the Prior Art

Passive devices such as capacitor, resistor, inductor or transformer are prevalently used in microwave or high-frequency communication applications. To comply with current requirements for light weight, slimness, and compactness, passive devices are integrated into single chip.

Please refer to FIG. 1, which is a schematic drawing illustrating a conventional inductor formed on a silicon substrate. As shown in FIG. 1, the conventional inductor 100 includes a spiral structure formed on a substrate 102. Two terminals 104a and 104b of the inductor 100 are electrically connected to a contact pad (not shown), respectively. When a current enters the inductor 100 from, for example but not limited to, the terminal 104a, a magnetic field 106 penetrating the silicon substrate 102 is generated by the current in clockwise direction. More important, image currents, also known as eddy currents 108 are induced in the silicon substrate 102 in a counterclockwise direction.

It is noteworthy that the inductor 100 includes an inductance value L and a quality factor Q. The quality factor Q (or Q factor) of the inductor 100 is a ratio of its inductive reactance to its resistance at a given frequency, and is a measure of its efficiency. It is well-known that eddy currents 108, which flow in a direction opposite to the current in the inductor 100, cause power loss, and thus quality factor Q is lowered. Briefly speaking, eddy currents 108 deteriorate performance of the inductor 100.

There is therefore a continuing need in the semiconductor processing art to avoid eddy currents and thus to improve quality factor Q of the inductor.

### SUMMARY OF THE INVENTION

According to an aspect of the present invention, an inductor formed on a semiconductor substrate is provided. The inductor formed on the semiconductor substrate provided by the present invention includes a semiconductor substrate, an inductor structure formed on the semiconductor substrate, and a plurality of slice structures formed in the semiconductor substrate. An extending direction of the slice structures is perpendicular to a surface of the semiconductor substrate.

According to the inductor formed on the semiconductor substrate, the slice structures are formed in the semiconductor substrate in order to obstruct eddy currents induced in the semiconductor substrate: Because eddy currents are parallel with a substrate-horizontal direction, the slice structures, of which the extending direction is perpendicular to the surface of the semiconductor substrate, cut and obstruct eddy currents effectively. Consequently, eddy currents are avoided and thus quality factor Q is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a conventional inductor formed on a silicon substrate.

FIGS. 2-4 are schematic drawings illustrating an inductor formed on a semiconductor substrate provided by a first preferred embodiment of the present invention, wherein

FIG. 3 is a top view of a portion of the inductor formed on the semiconductor substrate shown in FIG. 2.

FIG. 5 is a schematic drawing illustrating a modification to the preferred embodiment.

FIG. 6 is a schematic drawing illustrating another modification to the preferred embodiment.

FIG. 7 is a top view of a portion of the inductor formed on a semiconductor substrate provided by a second preferred embodiment of the present invention.

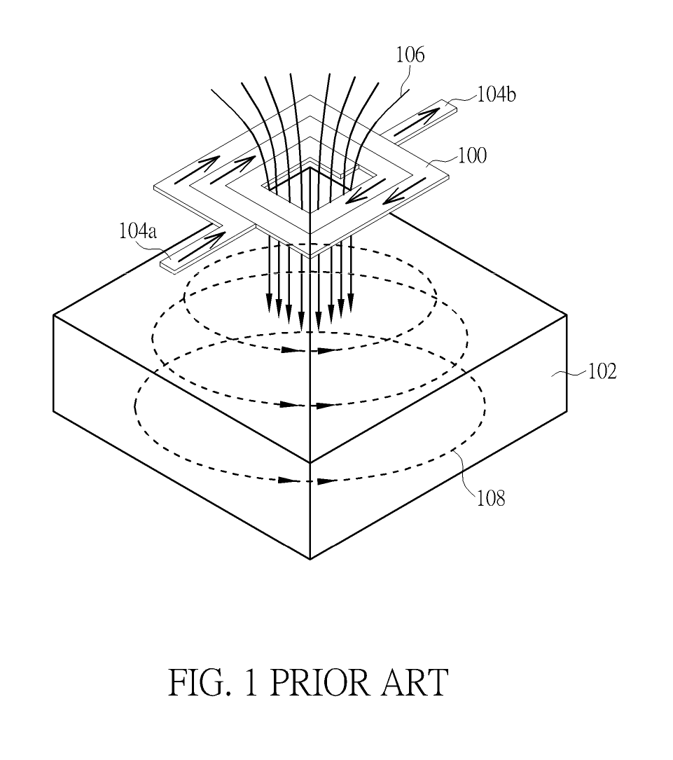

### DETAILED DESCRIPTION

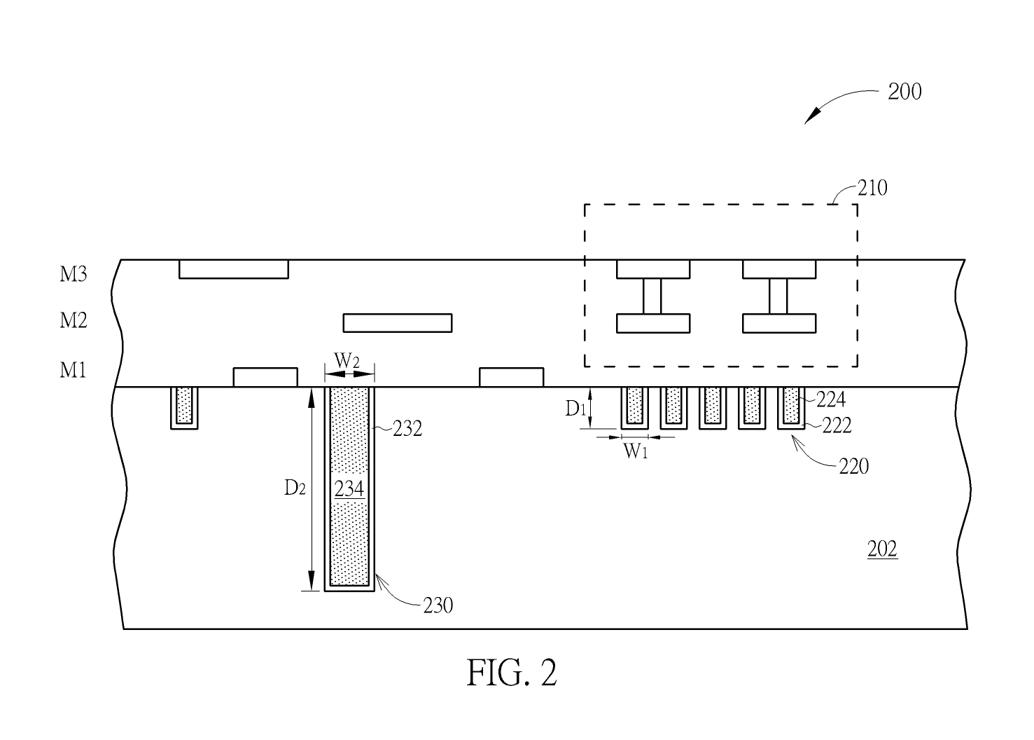

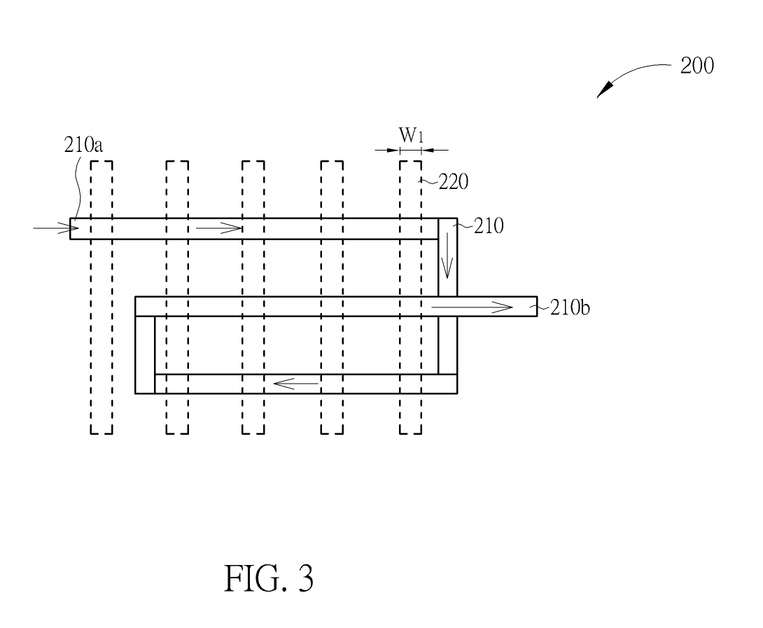

Please refer to FIGS. 2-4, which are schematic drawings illustrating an inductor formed on a semiconductor substrate provided by a first preferred embodiment of the present invention, wherein FIG. 3 is a top view of a portion of the inductor formed on the semiconductor substrate of FIG. 2. As shown in FIG. 2, the inductor formed on the semiconductor substrate includes a semiconductor substrate 202. The semiconductor substrate 202 can include an interposer, and the interposer preferably is a silicon substrate, but not limited to this. It is well-known to those skilled in the art that the interposer is arranged in between at least a function die and a carrier substrate and providing electrical connection between the function die and the carrier substrate. The semiconductor substrate 202 includes a plurality of interconnection layers M1-M3. It is also well-known to those skilled in the art that the interconnection layers M1-M3 include dielectric layers and wires and via plugs formed therein. Additionally, the amounts of the interconnection layers M1-M3 are only exemplarily shown in FIG. 2, but not limited to this. Furthermore, the inductor formed on the semiconductor substrate provided by the preferred embodiment can include a plurality of redistribution layers (RDLs) (not shown) on a surface of the interconnection layer M3, if required.

A plurality of passive devices such as capacitors, resistors, inductors, transformers, etc. can be formed in the semiconductor substrate 202 and the interconnection layers M1-M3. However there is no active device formed in the semiconductor substrate 202 and the interconnection layers M1-M3. According to the preferred embodiment, at least an inductor structure 210 is formed on the semiconductor substrate 202, particularly, formed in the interconnection layers M2 and M3. As shown in FIG. 2, the inductor structure 210 includes a spiral structure. The inductor structure 210 also includes a terminal 210a and a terminal 210b (shown in FIG. 3). Furthermore, a plurality of slice structures 220 and a plurality of through silicon via (hereinafter abbreviated as TSV) structures 230 are formed in the semiconductor substrate 202 according to the preferred embodiment. As shown in FIG. 2, an extending direction of the slice structures 220 and an extending direction of the TSV structures 230 are perpendicular to a surface of the semiconductor substrate 202. It is noteworthy that the slice structures 220 are disposed vertically and directly below the inductor structure 210. Therefore, the slice structures 220 are overlapped by the inductor structure 210 in the preferred embodiment. More important, the slice structures 220 are spaced apart from the inductor structure 210 as shown in FIG. 2. In detail, the inductor structure 210 is formed in the dielectric layers of the interconnection layers M1-M3 and physically and electrically isolated from the slice structures 220 by the dielectric layers of the interconnection layers M1-M3.

The slice structures 220 and the TSV structures 230 can be formed by the same fabricating processes. For example, a plurality of deep trenches (not shown) are formed in the semiconductor substrate 202 by a Laser process. Next, a dielectric layer is formed in the deep trenches and followed by filling the deep trenches with a conductive material. And a planarization process is then performed to complete the formation of the slice structures 220 and the TSV structures 230. Accordingly, the slice structures 220 respectively include a dielectric layer 222 and a conductive material 224 coated by the dielectric layer 222. Also, the TSV structures 230 respectively include a dielectric layer 232 and a conductive material 234 coated by the dielectric layer 232. As shown in FIG. 2, a top surface of the slice structures 220 and a top surface of the TSV structures 230 are coplanar with the surface of the semiconductor substrate 202. It is noteworthy that a width W₁ of the slice structures 220 is smaller than a diameter W₂ of the TSV structures 230. More important, a depth D₁ of the slice structures 220 is smaller than a depth D₂ of the TSV structures 230 in the preferred embodiment.

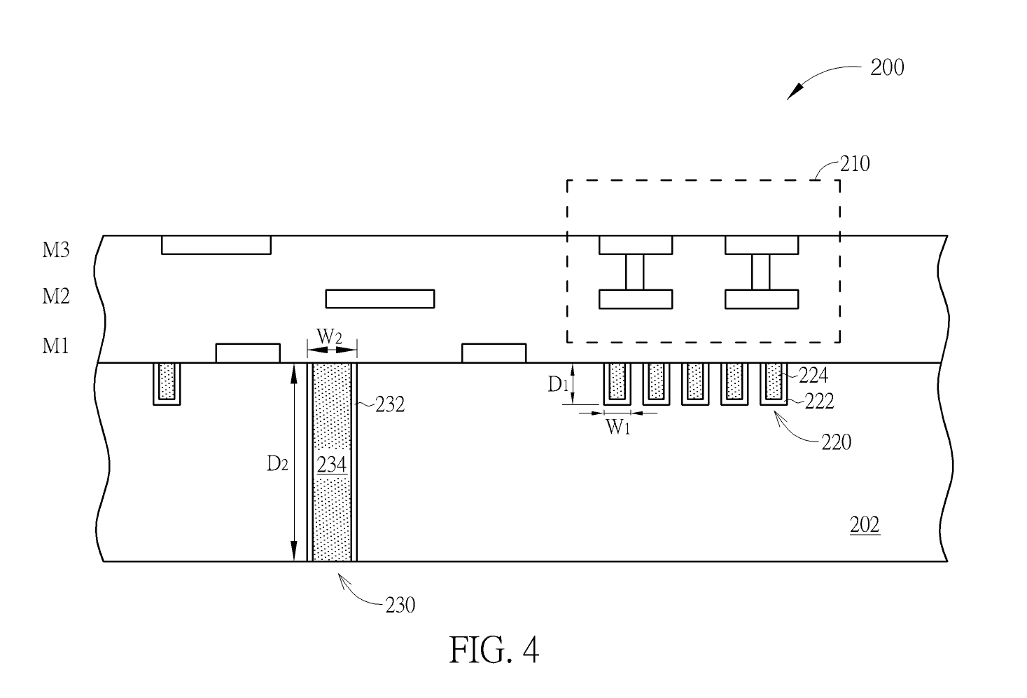

Please refer to FIG. 4. Next, a thinning process is performed from a backside of the semiconductor substrate 202. Consequently, the TSV structures 230 are exposed at the backside of the semiconductor substrate 202 and thus electric connection to outer circuit can be constructed. As mentioned above, the depth D₁ of the slice structures 220 is smaller than the depth D₂ of the TSV structures 230, therefore the slice structures 220 are not exposed but still buried in the semiconductor substrate 202 after the thinning process. More important, the slice structures 220 are electrically floated in the semiconductor substrate 202 by the dielectric layer 222 of the slice structures 220 and the dielectric layer of the interconnection layers M1-M3. According to the preferred embodiment, the slice structures 220 are electrically floated, that is, the slice structures 220 are electrically isolated from any device or component. However, the slice structures 220 can be grounded, if required.

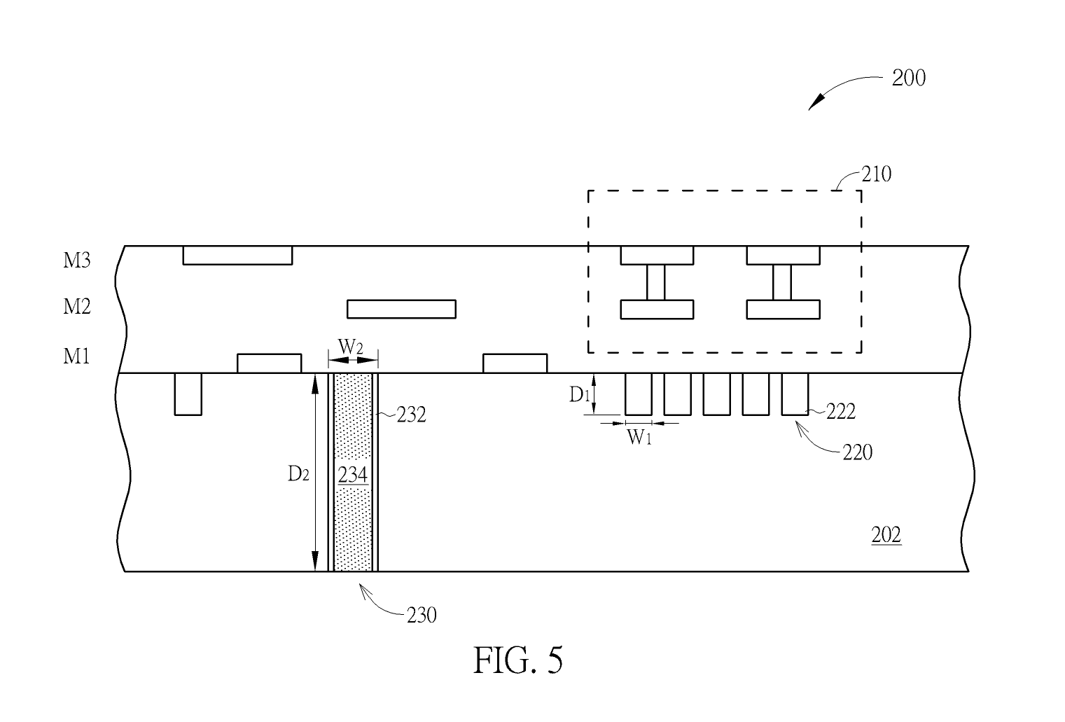

Please refer to FIG. 5, which is a schematic drawing illustrating a modification to the preferred embodiment. It should be noted that elements the same in the modification and the abovementioned preferred embodiment are designated by the same numerals and details are omitted in the interest of brevity. The difference between the modification and the abovementioned preferred embodiment is: Since the width W₁ of the slice structures 220 is smaller than the diameter W₂ of the TSV structures 230, the deep trenches in which the slice structures 220 are to be formed are closed during forming the dielectric layer 222 and a seam may be formed in the deep trenches. In another modification, the deep trenches in which the slice structures 220 are to be formed are even filled with the dielectric layer 222 as shown in FIG. 5. In such case, the slice structures 220 respectively include only the dielectric layer 222 while the TSV structures 230 respectively include the dielectric layer 232 and the conductive material 234 coated by the dielectric layer 232.

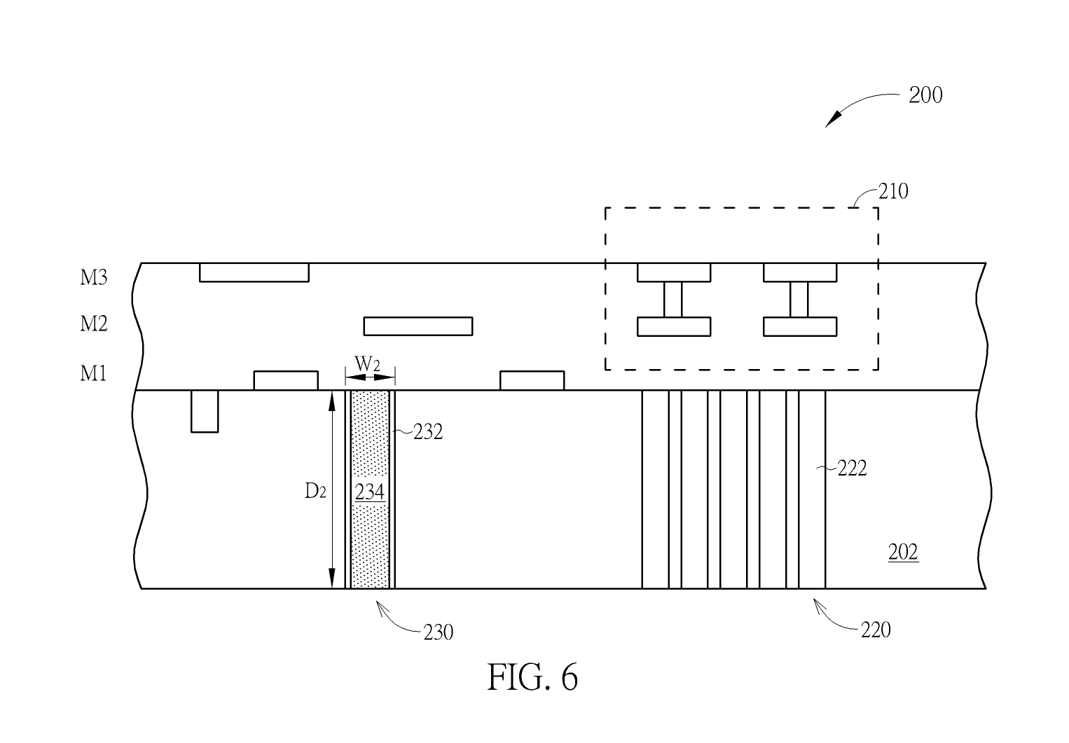

Please refer to FIG. 6, which is a schematic drawing illustrating another modification to the preferred embodiment. It should be noted that elements the same in the modification and the abovementioned preferred embodiment are also designated by the same numerals and details are omitted in the interest of brevity. The difference between the modification and the abovementioned preferred embodiment is: The depth D₁ of the slice structures 220 is equal to the depth D₂ of the TSV structures 230. Consequently, the slice structures 220 and the TSV structures 230 are all exposed at the backside of the semiconductor substrate 202. In the modification, the slice structures 220 are electrically floated, but not limited to this.

Please refer to FIG. 3 again. The slice structures 220 provided by the present invention are arranged in a grating pattern. And the slice structures 220 in the grating pattern are parallel with each other as shown in FIG. 3. It is well-known to those skilled in the art that the inductor structure 210 can include a spiral polygon structure or a spiral circle structure. When a current enters the inductor structure 210 from, for example but not limited to, the terminal 210a, a magnetic field penetrating the semiconductor substrate 202 is generated by the current in clockwise direction. And eddy currents in counterclockwise direction are induced vertically and directly under the inductor structure 210 in the semiconductor substrate 202. However, the slice structures 220 arranged in the grating pattern occupy the area where eddy currents are to be induced and thus eddy currents are cut and obstructed. In other words, eddy currents that are sufficient to impact the quality factor Q are effectively avoided by the slice structures 220.

According to the inductor formed on the semiconductor substrate 200 provided by the preferred embodiment, the slice structures 220 formed in the semiconductor substrate 202 obstruct eddy currents induced in the semiconductor substrate 202: Because eddy currents are parallel with a substrate-horizontal direction, the slice structures 220, of which the extending direction is perpendicular to the surface of the semiconductor substrate, cut and obstruct eddy currents effectively. Consequently, eddy currents are avoided and thus quality factor Q is improved.

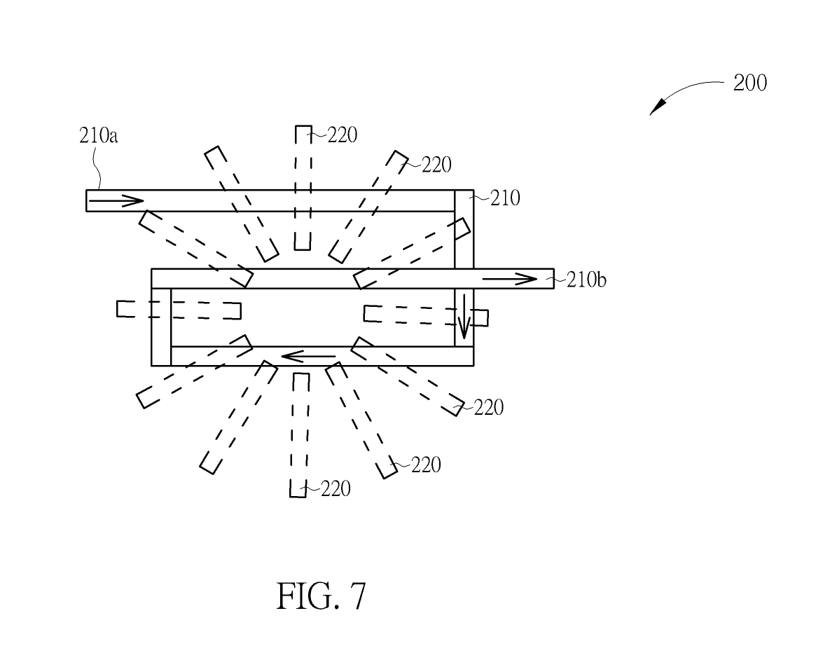

Please refer to FIG. 7, which is a top view of a portion of the inductor formed on a semiconductor substrate provided by a second preferred embodiment of the present invention. It should be noted that elements the same in the second preferred embodiment and the abovementioned first preferred embodiment are also designated by the same numerals and details are omitted in the interest of brevity. The difference between the second and the first preferred embodiments is: the slice structures 220 provided by the preferred embodiment are arranged in a radical pattern. As mentioned above, the inductor structure 210 can include a spiral polygon structure or a spiral circle structure. When a current enters the inductor structure 210 from, for example but not limited to, the terminal 210a, a magnetic field penetrating the semiconductor substrate 202 is generated by the current in clockwise direction. And eddy currents in counterclockwise direction are induced vertically and directly under the inductor structure 210 in the semiconductor substrate 202. However, the slice structures 220 arranged in the radical pattern occupy the area where eddy currents are to be induced and thus eddy currents are cut and obstructed. In other words, eddy currents that are sufficient to impact the quality factor Q are effectively avoided by the slice structures 220 the slice structures 220.

Additionally, those skilled in the art would easily realize the placements of other elements such as the TSV structures formed in the semiconductor substrate 202 and the interconnection layers formed on the semiconductor substrate 202 according to the abovementioned preferred embodiment. In the same concept, those skilled in the art would easily realize that the slice structures 220 can include only dielectric layer or include conductive material coated by the dielectric layer according to the abovementioned embodiment and modification. Also, those skilled in the art would easily realize that the depth D₁ of the slice structures 220 can be equal to or smaller than the depth D₂ of the TSV structures 230, and the slice structures 220 can be electrically floated or grounded according to the abovementioned embodiment and modification. Those details are therefore omitted for simplicity.

According to the inductor formed on the semiconductor substrate, the slice structures are formed in the semiconductor substrate in order to obstruct eddy currents induced in the semiconductor substrate: Because eddy currents are parallel with a substrate-horizontal direction, the slice structures, of which the extending direction is perpendicular to the surface of the semiconductor substrate, cut and obstruct eddy currents effectively. Consequently, eddy currents are avoided and thus quality factor Q is improved.

Those skilled in the art will readily observe that numerous modifications and alterations of the device and method may be made while retaining the teachings of the invention. Accordingly, the above disclosure should be construed as limited only by the metes and bounds of the appended claims.

1. An inductor formed on a semiconductor substrate, comprising:
a semiconductor substrate;
an inductor structure formed on the semiconductor substrate;
a plurality of through silicon via (TSV) structures formed in the semiconductor substrate;
a plurality of slice structures formed in the semiconductor substrate, an extending direction of the slice structures being perpendicular to a surface of the semiconductor substrate,
wherein the slice structures and the TSV structures respectively comprise a conductive material coated by a dielectric layer.

2. The inductor formed on the semiconductor substrate according to claim 1, wherein the slice structures are overlapped by and spaced apart from the inductor structure.

3. (canceled)

4. The inductor formed on the semiconductor substrate according to claim 1, wherein the semiconductor substrate comprises an interposer.

5. The inductor formed on the semiconductor substrate according to claim 1, wherein a width of the slice structures is smaller than a diameter of the TSV structures.

6-8. (canceled)

9. The inductor formed on the semiconductor substrate according to claim 1, wherein a depth of the slice structures is the same with a depth of the TSV structures.

10. The inductor formed on the semiconductor substrate according to claim 1, wherein a depth of the slice structures is smaller than a depth of the TSV structures.

11. The inductor formed on the semiconductor substrate according to claim 1, further comprising a plurality of interconnection layers formed on the semiconductor substrate, and the inductor structure is formed in the interconnection layers.

12. The inductor formed on the semiconductor substrate according to claim 1, wherein a top surface of the slice structures is coplanar with the surface of the semiconductor substrate.

13. The inductor formed on the semiconductor substrate according to claim 1, wherein the slice structures are electrically floated or grounded.

14. The inductor formed on the semiconductor substrate according to claim 1, wherein the slice structures are arranged in a grating pattern.

15. The inductor formed on the semiconductor substrate according to claim 1, wherein the slice structures are arranged in a radical pattern.

16. An inductor formed on a semiconductor substrate, comprising:
a semiconductor substrate;
an inductor structure formed on the semiconductor substrate;
a plurality of through silicon via (TSV) structures formed in the semiconductor substrate;
a plurality of slice structures formed in the semiconductor substrate, an extending direction of the slice structures being perpendicular to a surface of the semiconductor substrate,
wherein bottoms of the TSV structures and bottoms of the slice structures are exposed at a backside of the semiconductor substrate.

17. The inductor formed on the semiconductor substrate according to claim 16, wherein the slice structures comprise a dielectric material.

18. The inductor formed on the semiconductor substrate according to claim 17, wherein the TSV structures comprise a conductive material coated by a dielectric layer.

19. The inductor formed on the semiconductor substrate according to claim 16, wherein the TSV structures and the slice structures respectively comprise a conductive material coated by a dielectric layer.
